(19) United States
(12) Patent Application Publication
(10) Pub. No.: US 2021/0176885 A1
(43) Pub. Date: Jun. 10, 2021

(54) CONNECTING ELECTRICAL COMPONENTS

(71) Applicant: Siemens Aktiengesellschaft, Muenchen (DE)

(72) Inventors: Dirk POEHLER, Reinsdorf (DE); Joachim SEIDL, Sulzbach-Rosenberg (DE); Klaus WILKE, Berlin (DE); Dieter STEINDL, Poppenricht (DE)

(73) Assignee: Siemens Aktiengesellschaft, Muenchen (DE)

(21) Appl. No.: 17/047,763

(22) PCT Filed: Apr. 15, 2019
(86) PCT No.: PCT/EP2019/059608

§ 371 Date: Oct. 15, 2020

(30) Foreign Application Priority Data
Apr. 25, 2018 (EP) 18169242.7

(51) Int. Cl. H05K 7/14; H05K 7/18; H02B 1/04

(52) U.S. Cl. CPC H05K 7/1477; H05K 7/1438; B33Y 10/00; H02B 1/04; H05K 7/18

(57) ABSTRACT

A backplane is for electrically connecting electrical components, and a method is for producing the backplane. The backplane includes a mounting board, conductor tracks arranged on the mounting board, and at least one sensor unit. The method includes integrating the at least one sensor unit into the mounting board by an additive manufacturing method; printing the conductor tracks from an electrically conductive paste, the electrically conductive paste being cured after being applied to the mounting board, by way of 3D printing; and detecting and monitoring, via the at least one sensor unit, function of the conductor tracks during production of the backplane.

### PRIORITY STATEMENT

This application is the national phase under 35 U.S.C. § 371 of PCT International Application No. PCTEP2019/059608 which has an International filing date of Apr. 15, 2019, which designated the United States of America and which claims priority to European patent application EP18169242.7 filed Apr. 25, 2018, the contents of each of which are hereby incorporated by reference herein, in their entirety and for all purposes.

### FIELD

Embodiments of the invention generally relate to a backplane for electrically connecting electrical components and a method for producing a backplane of this kind. Embodiments of the invention further generally to a switchgear cabinet.

### BACKGROUND

Here, a backplane should be understood to be a carrier for electrical components having conductor tracks for electrically connecting the electrical components. Such electrical components are contactors, switches, control units or input/output units. Electrical components of a technical apparatus or system are arranged in a switchgear cabinet. In conventional switchgear cabinets, as a rule, electrical components are electrically interconnected by cables. Herein, the presence of numerous electrical components require a high outlay on cabling.

DE 10 2016 002 052 A1 (Liebherr-Components Biberach GmbH) Jun. 22, 2017 discloses a switchgear cabinet and a method for the production thereof. The switchgear cabinet has at least one switchboard with a base plate on which electrical switching elements are arranged and electrically interconnected. The at least one base plate and/or at least one of the switching elements is produced by way of a 3D printer in a 3D printing method.

### SUMMARY

At least one embodiment of the invention is directed to a backplane improved with respect to its functionality, a method for producing a backplane of this kind and an improved switchgear cabinet.

Embodiment of the invention are directed to a backplane, a switchgear cabinet and a method.

Advantageous embodiments of the invention are the subject matter of the claims.

A backplane according to at least one embodiment of the invention for electrically connecting electrical components comprises a mounting board, conductor tracks which are arranged on the mounting board and at least one sensor unit which is integrated into the mounting board.

A switchgear cabinet according to at least one embodiment of the invention has a backplane according to at least one embodiment of the invention.

With the method according to at least one embodiment of the invention for producing a backplane according to at least one embodiment of the invention, the at least one sensor unit is integrated into the mounting board by an additive manufacturing method. For example the at least one sensor unit is integrated into the mounting board in that, at least in a region surrounding the sensor unit, the mounting board is produced by way of 3D printing, which embeds the sensor unit in the mounting board. 3D printing should be understood to be a method with which a three-dimensional object is produced by computer-controlled layer-by-layer deposition of material.

### BRIEF DESCRIPTION OF THE DRAWINGS

The above-described properties, features and advantages of this invention and the manner in which these are achieved will become clear and more plainly comprehensible in conjunction with the following description of exemplary embodiments explained in more detail in conjunction with the drawings, in which:

FIG. 1 shows a schematic view of a backplane,

FIG. 2 shows a perspective depiction of a switchgear cabinet.

Mutually corresponding parts are given the same reference characters in the figures.

### DETAILED DESCRIPTION OF THE EXAMPLE EMBODIMENTS

A backplane according to at least one embodiment of the invention for electrically connecting electrical components comprises a mounting board, conductor tracks which are arranged on the mounting board and at least one sensor unit which is integrated into the mounting board.

Thus, in addition to conductor tracks, a backplane according to at least one embodiment of the invention also has at least one sensor unit which is integrated into the backplane. The integration of a sensor unit into the backplane advantageously increases the functionality of the backplane. Suitable sensor units are, for example, able to detect and monitor the function of conductor tracks, in particular as early as during the production and/or commissioning of the backplane, and/or operating conditions of the backplane. Monitoring of the function of the conductor tracks during the production is used for quality control; if, during the production of the backplane by way of an additive manufacturing method, a defect is determined in a conductor track, for example a current-interrupting gap in the conductor track, in that a current sensor which is also integrated into the mounting board for detecting an electric current in the conductor track does not detect any current flow, the defect in the affected conductor track can be rectified, for example by applying further printed layers of an electrically conductive paste.

The commissioning of the backplane can take place as a quality control step immediately after the production of a conductor track or a sensor unit; for example a conductor track arranged on the mounting board can be commissioned immediately after its production, for example by way of an additive manufacturing method, and its function checked; for example, a current sensor for detecting an electric current can measure a current flowing in the conductor track by applying an electric voltage. This advantageously enables the operational safety and the electrical reliability of the backplane to be increased, for example in that the maintenance of the backplane can be performed taking account of the detected sensor signals. The sensor signals detected by a sensor unit can, for example, be made available to a higher-level application. In particular, the sensor signals can be transmitted to a data cloud in which they are evaluated and/or used.

Embodiments of the invention provide that at least one sensor unit has a current sensor for detecting an electric current and/or that at least one sensor unit has a voltage sensor for detecting an electric voltage and/or that at least one sensor unit has a power sensor for detecting an electric power.

The aforementioned embodiments of the invention in particular enable the function of conductor tracks to be monitored by detecting electric currents flowing through the conductor tracks, electric voltages applied to the conductor tracks and/or electric power transmitted via the conductor tracks and in particular malfunctions and failures of conductor tracks to be identified. They further enable, for example, the identification of electric overvoltages and overcurrents so that electrical components can be switched off when necessary thus preventing damage to or the destruction of the electrical components.

Further embodiments of the invention provide that at least one sensor unit has a temperature sensor for detecting a temperature and/or that at least one sensor unit has a strain sensor for detecting deformation of the mounting board and/or that at least one sensor unit has a vibration sensor for detecting a vibration of the mounting board and/or that at least one sensor unit has an acceleration sensor for detecting an acceleration of the mounting board and/or that at least one sensor unit has a light sensor and/or that at least one sensor unit has a magnetometer and/or that at least one sensor unit has a gas sensor and/or that at least one sensor unit has a proximity switch.

The aforementioned embodiments of the invention enable operating conditions of the backplane to be detected and monitored. The detection and monitoring of a temperature enable, for example, imminent or actual overheating of the backplane and/or electrical components connected thereto to be identified in order to enable the timely implementation of countermeasures to prevent damage to or the destruction of the backplane and/or the electrical components due to overheating or to identify and rectify damage caused by overheating. The detection and monitoring of strain, acceleration and/or vibration of the mounting board enables, for example, imminent or actual mechanical overloading of the backplane by a mechanical voltage, a surge and/or a vibration in order to enable the timely implementation of countermeasures to prevent damage to or the destruction of the backplane due to mechanical overloading or to identify and rectify damage caused by mechanical overloading. The detection and monitoring of incident light or a gas in the vicinity of the backplane enables, for example, the identification of the development of smoke (for example by a sensor embodied as a smoke detector) and hence of the risk of fire in the vicinity of the backplane. In the case of a backplane arranged in a switchgear cabinet, the detection and monitoring of incident light enables, for example, it to be identified whether the switchgear cabinet is being opened. A proximity switch enables, for example, it to be identified whether a person is approaching the backplane, for example in order to warn the person of high voltage.

A switchgear cabinet according to at least one embodiment of the invention has a backplane according to at least one embodiment of the invention.

The use of a backplane according to at least one embodiment of the invention in a switchgear cabinet advantageously reduces the outlay and costs for electrically connecting electrical components in the switchgear cabinet compared to the conventional connection of electrical components by way of cables. In addition, the integration of at least one sensor unit into the backplane has the aforementioned advantages of enabling the function of the conductor tracks and the operating conditions of the backplane to be detected and monitored in particular to improve the operating safety and maintenance of backplane.

With the method according to at least one embodiment of the invention for producing a backplane according to at least one embodiment of the invention, the at least one sensor unit is integrated into the mounting board by an additive manufacturing method. For example the at least one sensor unit is integrated into the mounting board in that, at least in a region surrounding the sensor unit, the mounting board is produced by way of 3D printing, which embeds the sensor unit in the mounting board. 3D printing should be understood to be a method with which a three-dimensional object is produced by computer-controlled layer-by-layer deposition of material.

The integration of a sensor unit into the mounting board by an additive manufacturing method, in particular by embedding the sensor unit in the mounting board by way of 3D printing, enables the backplane to be efficiently equipped with the sensor unit. In particular, there is no need for complex subsequent fastening of the sensor unit on the mounting board and the fastening structures required for this purpose.

A further embodiment of the invention provides that the conductor tracks are applied to the mounting board by way of 3D printing. For example, the conductor tracks are printed from an electrically conductive paste, in particular a copper paste, aluminum paste, brass paste or silver paste.

The aforementioned embodiment of the invention takes account of the fact that different configurations of components to be electrically connected also require different conductor track cross sections and paths. For example, power lines require thicker conductor tracks than signal lines and different arrangements of components require different conductor track paths. Manufacturing the conductor tracks by way of 3D printing enables the conductor track cross sections and paths to be easily and flexibly adapted to the configuration of respective components to be electrically connected. This in particular enables cost-effective series production of backplanes for different configurations of electrical components. 3D printing of the conductor tracks from an electrically conductive curable paste is advantageous since paste is easy to apply and does not run after application and can be stabilized by curing. Copper pastes, aluminum pastes, brass pastes and silver pastes are particularly suitable as material for 3D printing of the conductor tracks due to their good electrical conductivity.

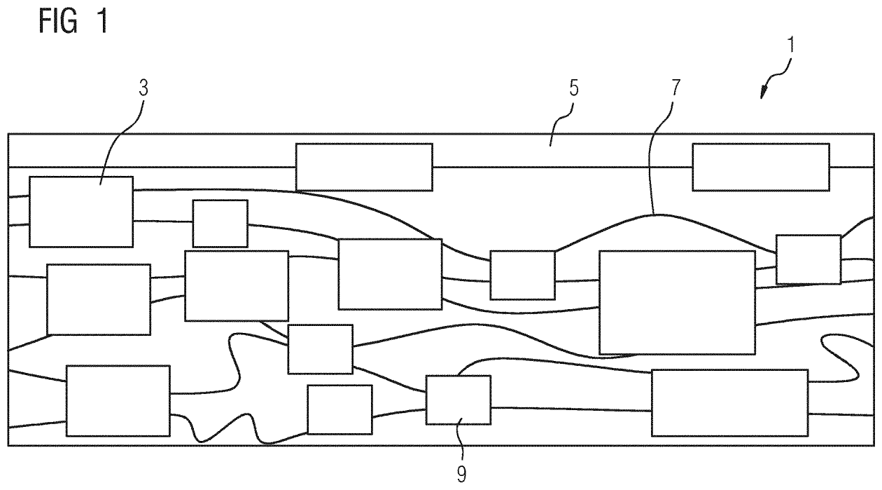

FIG. 1 shows a schematic depiction of a backplane 1 in a top view of the backplane 1. A plurality of electrical components 3 are arranged on the backplane 1.

An electrical component 3 can, for example, be a contactor, a switch, a control unit, an input/output unit, a soft starter or a frequency converter.

The backplane 1 has a mounting board 5, conductor tracks 7 arranged on the mounting board 5 and sensor units 9 which are integrated into the mounting board 5.

The conductor tracks 7 in each case electrically interconnect electrical components 3 and/or sensor units 9.

A sensor unit 9 can, for example, be a current sensor for detecting an electric current, a voltage sensor for detecting an electric voltage, a temperature sensor for detecting a temperature, a power sensor for detecting an electric power, a strain sensor for detecting a deformation of the mounting board 5, a vibration sensor for detecting a vibration of the mounting board 5, an acceleration sensor for detecting an acceleration of the mounting board 5, a light sensor, a magnetometer, a gas sensor, a proximity switch or an evaluating unit for evaluating sensor signals.

During the production of the backplane 1, the sensor units 9 are integrated into the mounting board 5 by an additive manufacturing method. For example, at least in each region surrounding a sensor unit 9, the mounting board 5 is produced by way of 3D printing, which embeds the respective sensor unit 9 in the mounting board 5. Further, during the production of the backplane 1, the conductor tracks 7 are, for example, applied to the mounting board 5 by way of 3D printing. For example, the conductor tracks 7 are printed from an electrically conductive paste, in particular from a copper paste, aluminum paste, brass paste or silver paste, which is cured after being applied to the mounting board 5.

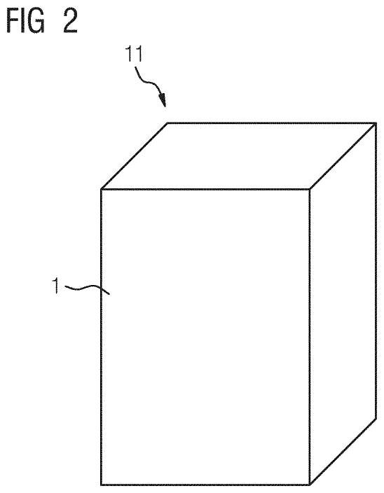

FIG. 2 is a perspective depiction of a switchgear cabinet 11. The switchgear cabinet 11 has a backplane 1 as described with reference to FIG. 1 that forms a rear wall of the switchgear cabinet 11.

Although the invention was illustrated and described in greater detail by preferred exemplary embodiments, the invention is not restricted by the disclosed examples and other variations can be derived herefrom by the person skilled in the art without departing from the scope of protection of the invention.

1. A method for producing a backplane for electrically connecting electrical components, the backplane including a mounting board, conductor tracks arranged on the mounting board, and at least one sensor unit, the method comprising:
integrating the at least one sensor unit into the mounting board by an additive manufacturing method;
printing the conductor tracks from an electrically conductive paste, the electrically conductive paste being cured after being applied to the mounting board, by way of 3D printing; and
detecting and monitoring, via the at least one sensor unit, the function of the conductor tracks during production of the backplane.

2. The method of claim 1, wherein the integrating of the at least one sensor unit into the mounting board includes, at least in a region surrounding the sensor unit, the mounting board being produced via 3D printing, to embed the at least one sensor unit in the mounting board and thereby integrate the at least one sensor into the mounting board.

3. The method of claim 1, wherein the at least one sensor unit includes a current sensor for detecting an electric current.

4. The method of claim 1, wherein the at least one sensor unit includes a voltage sensor for detecting an electric voltage.

5. The method of claim 1, wherein the at least one sensor unit a temperature sensor for detecting a temperature.

6. The method of claim 1, wherein the at least one sensor unit includes a strain sensor for detecting a deformation of the mounting board.

7. The method of claim 1, wherein the at least one sensor unit includes an acceleration sensor for detecting an acceleration of the mounting board.

8. The method of claim 1, wherein the at least one sensor unit includes a light sensor.

9. The method of claim 1, wherein the at least one sensor unit includes a magnetometer.

10. The method of claim 1, wherein the at least one sensor unit includes a gas sensor.

11. The method of claim 1, wherein the at least one sensor unit includes a proximity switch.

12.-15. (canceled)

16. The method of claim 2, wherein at least one sensor unit includes a current sensor for detecting an electric current.

17. The method of claim 2, wherein at least one sensor unit includes a voltage sensor for detecting an electric voltage.

18. The method of claim 2, wherein the at least one sensor unit a temperature sensor for detecting a temperature.

19. The method of claim 2, wherein the at least one sensor unit includes a strain sensor for detecting a deformation of the mounting board.

20. The method of claim 2, wherein the at least one sensor unit includes an acceleration sensor for detecting an acceleration of the mounting board.

21. The method of claim 2, wherein the at least one sensor unit includes a light sensor.

22. The method of claim 2, wherein the at least one sensor unit includes a magnetometer.

23. The method of claim 2, wherein the at least one sensor unit includes a gas sensor.

24. The method of claim 2, wherein the at least one sensor unit includes a proximity switch.
